(19) United States
(12) Patent Application Publication
(10) Pub. No.: US 2026/0170983 A1
(43) Pub. Date: Jun. 18, 2026

(54) SCAN DRIVING CIRCUIT, DRIVING METHOD THEREOF AND DISPLAY PANEL

(71) Applicant: Yungu (Gu’an) Technology Co., Ltd., Langfang (CN)

(72) Inventors: Enqing GUO, Langfang (CN); Junfeng LI, Langfang (CN); Cuili GAI, Langfang (CN); Kangguan PAN, Langfang (CN); Yun CHENG, Langfang (CN)

(73) Assignee: Yungu (Gu’an) Technology Co., Ltd., Langfang (CN)

(21) Appl. No.: 19/533,289

(22) Filed: Feb. 9, 2026

Related U.S. Application Data
(63) Continuation of application No. PCT/CN2024/108870, filed on Jul. 31, 2024.

(30) Foreign Application Priority Data
Aug. 17, 2023 (CN) 202311040130.3

(51) Int. Cl. G09G 3/20

(52) U.S. Cl. CPC G09G 3/20; G09G 2310/0267; G09G 2310/0286

(57) ABSTRACT

The present application discloses a scan driving circuit, a driving method thereof, and a display panel. The scan driving circuit includes: an input module configured to generate a first control signal at a first node; a level transmission module configured to generate a second control signal at a third node; an output module including a first control terminal and a second control terminal, and the first control terminal and the second control terminal are respectively configured to be electrically connected to the input module and the level transmission module to generate a corresponding scan output signal in response to the first control signal and the second control signal; and a first isolation module located between the second control terminal of the output module and the third node.

### CROSS-REFERENCE TO RELATED APPLICATION

The present application a continuation of International Application No. PCT/CN2024/108870 filed on Jul. 31, 2024, which claims priority to Chinese Patent Application No. 202311040130.3, titled “SCAN DRIVING CIRCUIT, DRIVING METHOD THEREOF AND DISPLAY PANEL” and filed on Aug. 17, 2023, which is hereby incorporated by reference in its entirety.

### FIELD

The present application relates to the field of display technology, and in particular to a scan driving circuit, a driving method thereof and a display panel.

### BACKGROUND

Gate Driver on Array (GOA) technology integrates a scan driving circuit on an array substrate to generate scan signals for pixel units, enabling row-by-row scanning.

However, existing scan driving circuits have poor reliability.

### SUMMARY

The main problem addressed by the present application is to provide a scan driving circuit, a driving method thereof, and a display panel, which can solve the problems of poor reliability under long-term use of the scan driving circuit and significant signal glitches in the output signal.

The first technical solution provided by the present application is: to provide a scan driving circuit, and the scan driving circuit includes: an input module, configured to generate a first control signal at a first node; a level transmission module, configured to generate a second control signal at a third node; an output module, including a first control terminal and a second control terminal, and the first control terminal and the second control terminal are respectively configured to be electrically connected to the input module and the level transmission module, to generate a corresponding scan output signal in response to the first control signal and the second control signal; and a first isolation module, located between the second control terminal of the output module and the third node.

The second technical solution provided by the present application is: to provide a driving method, applied to the aforementioned scan driving circuit, and the driving method includes: in a first phase, a scan input signal is provided at a first level state, and a first clock signal, a second clock signal and a third clock signal are at the first level state, to generate a first control signal at the first node, and the output module generates a first scan output signal in response to the first control signal; in a second phase, the scan input signal is provided at a second level state, a first clock signal and the third clock signal are provided at the first level state, and the output module continuously generates the first scan output signal; in a third phase, the second clock signal is provided at the first level state, to generate a second control signal at the third node, and the output module generates a second scan output signal in response to the second control signal; in a fourth phase, the scan input signal is provided at the first level state, the second clock signal is provided at the second level state, the first clock signal and the third clock signal are provided at the first level state, to generate the first control signal at the first node, and the output module generates the first scan output signal in response to the first control signal; in a fifth phase, the second clock signal is provided at the first level state, and the output module continuously generates the first scan output signal.

The third technical solution provided by the present application is: to provide a display panel, and the display panel includes a scan driving circuit and pixel units coupled thereto; and the scan driving circuit is the aforementioned scan driving circuit.

The scan driving circuit provided by the present application can reduce the voltage difference between the level transmission module and the output module, thereby stably outputting scan output signals and effectively improving the reliability of the scan driving circuit.

### BRIEF DESCRIPTION OF THE DRAWINGS

FIG. 1 is a schematic structural diagram of a first embodiment of the scan driving circuit of the present application;

FIG. 2 is a schematic structural diagram of a second embodiment of the scan driving circuit of the present application;

FIG. 3 is a schematic structural diagram of a third embodiment of the scan driving circuit of the present application;

FIG. 4 is a schematic structural diagram of a fourth embodiment of the scan driving circuit of the present application;

FIG. 5 is a schematic structural diagram of a fifth embodiment of the scan driving circuit of the present application;

FIG. 6 is a schematic structural diagram of a sixth embodiment of the scan driving circuit of the present application;

FIG. 7 is a schematic structural diagram of a seventh embodiment of the scan driving circuit of the present application;

FIG. 8 is a schematic structural diagram of an eighth embodiment of the scan driving circuit of the present application;

FIG. 9 is a schematic structural diagram of a ninth embodiment of the scan driving circuit of the present application;

FIG. 10 is a schematic structural diagram of a tenth embodiment of the scan driving circuit of the present application;

FIG. 11 is a schematic structural diagram of an eleventh embodiment of the scan driving circuit of the present application;

FIG. 12 is a schematic structural diagram of an embodiment of the scan driving circuit in FIG. 11;

FIG. 13 is a schematic timing diagram of an embodiment of various input signals corresponding to the scan driving circuit in FIG. 12;

FIG. 14 is a schematic structural diagram of an embodiment obtained by cascading the scan driving circuit in FIG. 12;

FIG. 15 is another schematic structural diagram of an embodiment of the scan driving circuit in FIG. 11;

FIG. 16 is yet another schematic structural diagram of an embodiment of the scan driving circuit in FIG. 11;

FIG. 17 is a schematic flowchart of an embodiment of the driving method of the present application;

FIG. 18 is a schematic structural diagram of an embodiment of the display panel of the present application.

### DETAILED DESCRIPTION

The present application will be described in detail below with reference to the accompanying drawings and embodiments.

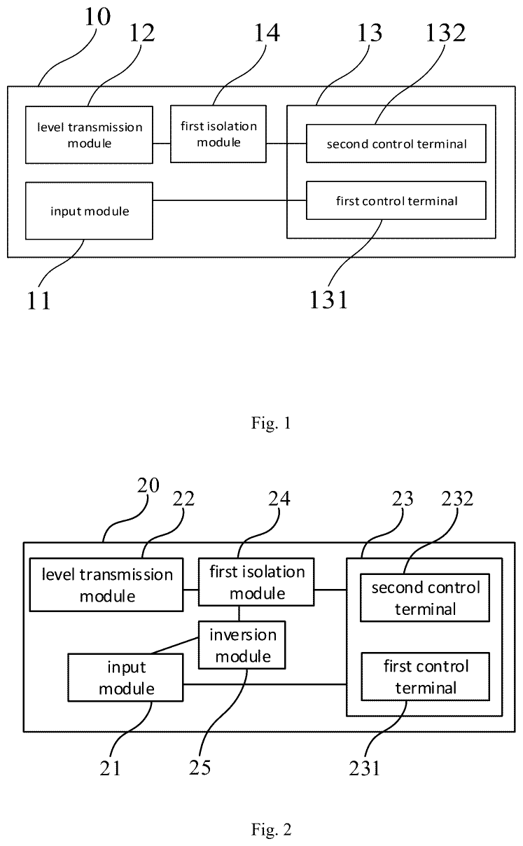

Refer to FIG. 1. FIG. 1 is a schematic structural diagram of a first embodiment of the scan driving circuit of the present application. In this embodiment, the scan driving circuit 10 includes: an input module 11, a level transmission module 12, an output module 13, and a first isolation module 14.

In the field of display technology, a display panel typically includes a display area and a non-display area disposed around the periphery of the display area. In the display area, a plurality of scan lines S1, S 2...Sn (where n is an integer greater than 1) and data lines D1, D2...Dm (where m is an integer greater than 1) intersecting the plurality of scan lines are further provided to define a plurality of pixel units. In the non-display area, a scan driving circuit 10, a data driving circuit, an enable signal control circuit, and a timing control circuit are further provided. Among these, the scan driving circuit 10 is connected to the scan lines and is used to generate scan output signals input to the pixel units to control the writing operation of data signals. The data driving circuit is connected to the data lines and is used to provide data signals to the pixel units to drive the pixel units for corresponding image display. The enable signal control circuit is connected to the emission control traces EM1, EM2...EMn and is used to provide enable signals to the pixel units. The timing control circuit is used to provide clock signals to the pixel units. Moreover, the scan driving circuit 10 includes multiple stage circuits, i.e., multi-stage scan circuits, connected to pixel rows via multiple scan lines. Each scan circuit provides a scan signal to its corresponding scan line.

The input module 11 is used to generate a first control signal at a first node, while the level transmission module 12 is used to generate a second control signal at a third node.

Here, the first node and the third node refer to two connection endpoints between various modules in the scan driving circuit 10 that can respectively generate the first control signal and the second control signal.

Furthermore, the output module 13 also includes a first control terminal 131 and a second control terminal 132. The first control terminal 131 is used to electrically connect to the input module 11 to receive the first control signal sent by the input module 11. The second control terminal 132 is used to electrically connect to the level transmission module 12 to receive the second control signal sent by the level transmission module 12, thereby enabling the output module 13 to trigger an action in response to the level states of the first control signal and the second control signal to generate a corresponding scan output signal.

The first isolation module 14 is correspondingly disposed between the second control terminal 132 of the output module 13 and the third node, and the level transmission module 12 sends the second control signal generated at the third node to the output module 13 via the first isolation module 14. This can avoid a large voltage difference caused by changes in the conduction state of the output module 13, which could cause impact damage to the level transmission module 12 and, in turn, affect the stable output of the scan output signal.

In the present application, “coupled” includes any direct and indirect connection means. Therefore, if it is described that a first element is coupled to a second element, it means that the first element can be directly connected to the second element through electrical connection, communication connection, wireless transmission, optical transmission, or other signal connection methods, or indirectly electrically or signal-connected to the second element through other elements or connection means.

The above solution provides a novel scan driving circuit 10. By arranging the first isolation module 14 between the second control terminal 132 of the output module 13 and the third node, the voltage difference between the level transmission module 12 and the output module 13 is minimized, thereby enabling stable output of the scan output signal and effectively improving the reliability of the circuit.

In one embodiment, the input module 11 is used to receive a third clock signal correspondingly provided by an external timing control circuit, as well as an externally input start signal or an output signal from a previous-stage scan driving circuit 10, to serve as a scan input signal. It triggers an action in response to the level state of the third clock signal to sample the scan input signal, thereby generating a first control signal at a first node in the scan driving circuit 10.

The level transmission module 12 is used to receive a first clock signal and a second clock signal correspondingly provided by the timing control circuit. It triggers an action in response to the level states of the first clock signal and the second clock signal to sample a first level signal, thereby generating a second control signal at a third node in the scan driving circuit 10.

The input module 11 is coupled to a node of the timing control circuit, as well as to a start signal providing terminal of a system processing circuit or an output terminal of a previous-stage scan driving circuit 10, to receive the third clock signal correspondingly sent by the timing control circuit, and the scan input signal sent by the system processing circuit or the previous-stage scan driving circuit 10. Similarly, the level transmission module 12 is coupled to two other nodes of the timing control circuit to receive the first clock signal and the second clock signal correspondingly sent by the timing control circuit.

The first clock signal, the second clock signal, and the third clock signal have the same period. The phase difference between the second clock signal and the first clock signal is half a period, and a rising edge of the third clock signal occurs at or after the falling edge of the second clock signal.

The first clock signal, the second clock signal, and the third clock signal are square wave periodic signals, and within one period, the pulse width at the high level is twice the pulse width at the low level.

The input module 11 and the level transmission module 12 use the first clock signal, the second clock signal, the third clock signal, and the first level signal to trigger actions, thereby generating the first control signal at the first node and the second control signal at the third node, respectively. Then, the first control signal and the second control signal are used to trigger the output module 13 to turn on or off, correspondingly outputting a scan output signal at a high level or a low level. This scan output signal is sent to the corresponding scan line and output to the corresponding pixel unit.

FIG. 2 is a schematic structural diagram of a second embodiment of the scan driving circuit of the present application. This embodiment is based on the first embodiment of the scan driving circuit provided by the present application. The scan driving circuit 20 further includes an inversion module 25.

The inversion module 25 is used to receive the first control signal sent from the first node and the second clock signal sent from the timing control circuit. It responds to the first control signal at the first node and the second clock signal to sample a second level signal and transmit this second level signal to the third node.

The first level signal may be a low level signal, and the second level signal may be a high level signal; in one embodiment, the first level signal may be a high level signal, and the second level signal may be a low level signal. The inversion module 25 uses the first control signal at a low level and the second clock signal to transmit the second level signal at a high level to the third node; or, uses the first control signal at a high level and the second clock signal to transmit the second level signal at a low level to the third node.

In this embodiment, the input module 21, the level transmission module 22, the output module 23, the first control terminal 231, the second control terminal 232, and the first isolation module 24 are respectively the same as the input module 11, the level transmission module 12, the output module 13, the first control terminal 131, the second control terminal 132, and the first isolation module 14. For details, refer to FIG. 1 and the related description.

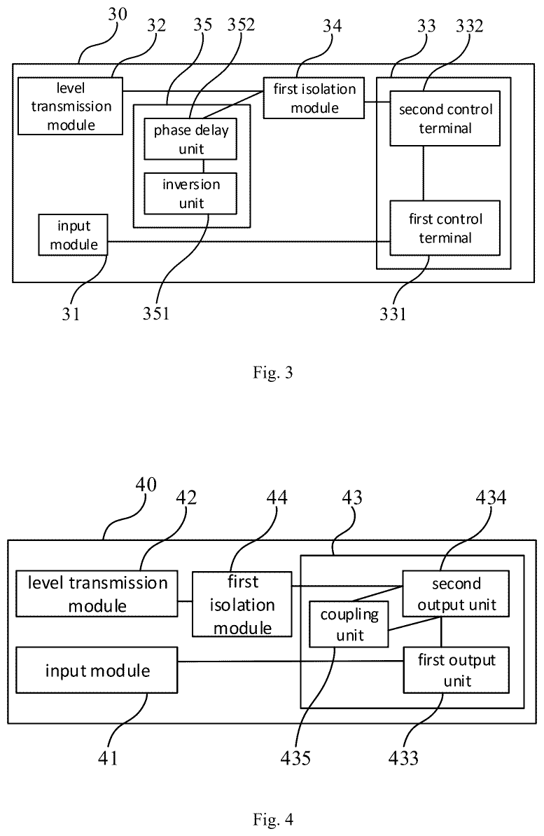

FIG. 3 shows a schematic structural diagram of a third embodiment of the scan driving circuit according to the present application. This embodiment is based on the second embodiment of the scan driving circuit provided in the present application. The inversion module 35 in the scan driving circuit 30 further includes an inversion unit 351 and a phase delay unit 352.

The inversion unit 351 is connected to the first node, and the phase delay unit 352 is connected to the inversion unit 351 and the third node. The inversion unit 351 is configured to receive the first control signal sent by the first node, sample the second level signal in response to the first control signal on the first node, and transmit the second level signal to the phase delay unit 352. The phase delay unit 352 is further configured to receive the second clock signal sent by the timing control circuit, trigger an action in response to the level state of the second clock signal, perform phase delay on the second level signal, and transmit it to the third node.

Since a rising edge of the third clock signal occurs at or after the falling edge of the second clock signal, when the third clock signal is used to generate the first control signal at the first node and then the first control signal is used to sample the second level signal, the phase delay unit 352 triggers an action in response to the second clock signal whose falling edge is not later than the rising edge of the third clock signal. After phase delay, the second level signal output by the inversion unit 351 is transmitted to the third node, thereby effectively reducing signal glitches in the scan output signal correspondingly output by the output module 33.

In one embodiment, the inversion unit 351 includes a sixth transistor, and the phase delay unit includes a fifteenth transistor. The first terminal of the sixth transistor is connected to the supply terminal of the second level signal, the control terminal of the sixth transistor is connected to the first node, the second terminal of the sixth transistor is connected to the first terminal of the fifteenth transistor, the control terminal of the fifteenth transistor is connected to the supply terminal of the second clock signal, and the second terminal of the fifteenth transistor is connected to the third node.

The control terminal of the sixth transistor can trigger an action in response to the first control signal on the first node, to turn on the first terminal and the second terminal of the sixth transistor, thereby transmitting the second level signal to the first terminal of the fifteenth transistor. The control terminal of the fifteenth transistor can trigger an action in response to the second clock signal, to turn on the first terminal and the second terminal of the fifteenth transistor, thereby transmitting the second level signal to the third node. By adjusting the level states of the first control signal and the second clock signal, the triggering times of the sixth transistor and the fifteenth transistor can be adjusted, thereby effectively achieving phase delay of the second level signal and effectively reducing signal glitches in the scan output signal correspondingly output by the output module 33.

Each of the aforementioned transistors may be a P-type thin-film transistor, an N-type thin-film transistor, or a field-effect transistor. The control terminal of each transistor may be a gate, with the first terminal being a drain and the second terminal being a source; in one embodiment, the control terminal of each transistor may be a gate, with the first terminal being a source and the second terminal being a drain. The same applies below and will not be repeated.

Each of the aforementioned transistors may also be a composite transistor or a single transistor, which is not limited in the present application.

In other embodiments, the transistor may be replaced by a triode. The control terminal of each triode is a base, with the first terminal being a collector and the second terminal being an emitter; in one embodiment, the control terminal of each triode is a base, with the first terminal being an emitter and the second terminal being a collector, which is not limited in the present application.

In this embodiment, the input module 31, the level transmission module 32, the output module 33, the first control terminal 331, the second control terminal 332, and the first isolation module 34 are respectively the same as the input module 21, the level transmission module 22, the output module 23, the first control terminal 231, the second control terminal 232, and the first isolation module 24. For details, refer to FIG. 2 and the related text content, which will not be repeated here.

FIG. 4 illustrates a fourth embodiment of the scan driving circuit, based on the first embodiment. In this embodiment, the output module 43 includes a first output unit 433 and a second output unit 434.

The control terminal of the first output unit 433 serves as the first control terminal of the output module 43, and the control terminal of the second output unit 434 serves as the second control terminal of the output module 43. The first terminal of the first output unit 433 receives the first level signal, the second terminal of the first output unit 433 is connected to the output terminal of the output module 43, the first terminal of the second output unit 434 receives the third clock signal, and the second terminal of the second output unit 434 is connected to the output terminal of the output module 43.

The first output unit 433 can trigger an action in response to the first control signal, to transmit the first level signal as a scan output signal to the output terminal of the output module 43. The second output unit 434 can trigger an action in response to the second control signal, to transmit the third clock signal as a scan output signal to the output terminal of the output module 43. This allows copying a portion of the third clock signal to output to the next-stage scan driving circuit 40 and the scan line, serving as the scan input signal for the next-stage scan driving circuit 40 and the driving signal for the pixel unit.

The output module 43 further includes a coupling unit 435. A first terminal of the coupling unit 435 is connected to a control terminal of the second output unit 434, while a second terminal of the coupling unit 435 is connected to a second terminal of the second output unit 434, to effectively reduce the coupling effect of the output module 43, thereby reducing fluctuations in the scan output signal and ensuring stable output of the scan output signal.

In one embodiment, the first output unit 433 includes a tenth transistor, the second output unit 434 includes a ninth transistor, and the coupling unit 435 includes a third capacitor. A first terminal of the tenth transistor is connected to a supply terminal of a first voltage signal, a control terminal of the tenth transistor is connected to a first control terminal, and a second terminal of the tenth transistor is connected to an output terminal of the output module 43. A first terminal of the ninth transistor is connected to a supply terminal of a third clock signal, a control terminal of the ninth transistor is connected to a first terminal of the third capacitor and a second control terminal, and a second terminal of the ninth transistor is connected to a second terminal of the third capacitor and the output terminal of the output module 43.

The control terminal of the tenth transistor can respond to a first control signal on the first control terminal to trigger an action, thereby turning on the first terminal and the second terminal of the tenth transistor to transmit the first voltage signal to the output terminal of the output module 43. The control terminal of the ninth transistor can respond to a second control signal on the second control terminal to trigger an action, thereby turning on the first terminal and the second terminal of the ninth transistor to transmit the third clock signal to the output terminal of the output module 43, thereby replicating a portion of the third clock signal. The third capacitor is used to stabilize the voltage at the output terminal of the output module 43.

In this embodiment, the input module 41, the level transmission module 42, and the first isolation module 44 are respectively the same as the input module 11, the level transmission module 12, and the first isolation module 14. For details, refer to FIG. 1 and the related text content, which will not be repeated here.

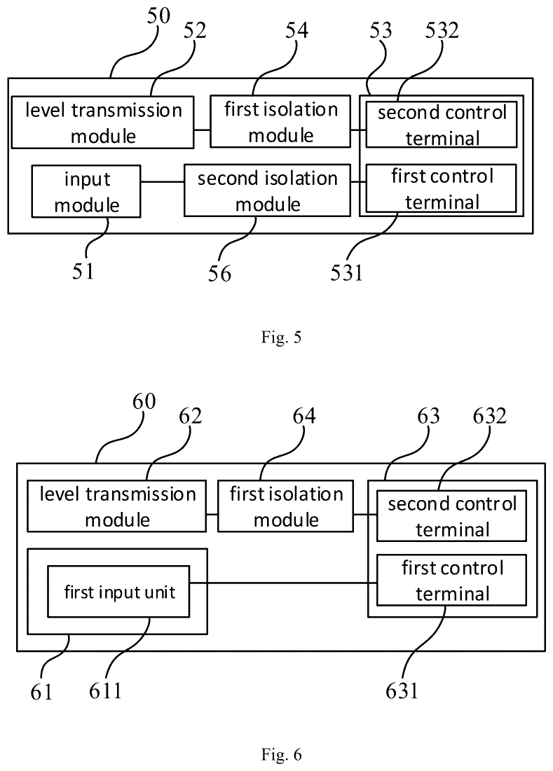

FIG. 5 is a schematic structural diagram of a fifth embodiment of the scan driving circuit of the present application. This embodiment is based on the first embodiment of the scan driving circuit provided in the present application. The scan driving circuit 50 further includes a second isolation module 56.

The second isolation module 56 is disposed between a first control terminal of the output module 53 and a first node, to isolate a large voltage swing, such as an extremely low voltage level, caused by changes in the conduction state of the output module 53, thereby avoiding impact damage to the input module 51 and, in turn, affecting the stable output of the scan output signal.

In this embodiment, the input module 51, the level transmission module 52, the output module 53, the first control terminal 531, the second control terminal 532, and the first isolation module 54 are respectively the same as the input module 11, the level transmission module 12, the output module 13, the first control terminal 131, the second control terminal 132, and the first isolation module 14. For details, refer to FIG. 1 and the related text content, which will not be repeated here.

FIG. 6 is a schematic structural diagram of a sixth embodiment of the scan driving circuit of the present application. This embodiment is based on the first embodiment of the scan driving circuit provided in the present application. The input module 61 in the scan driving circuit 60 further includes a first input unit 611.

The input module 61 uses the first input unit 611 to receive a third clock signal correspondingly provided by a timing control circuit, as well as an externally input start signal or an output signal from a previous-stage scan driving circuit 60, to sample the scan input signal in response to the third clock signal.

In this embodiment, the input module 61, the level transmission module 62, the output module 63, the first control terminal 631, the second control terminal 632, and the first isolation module 64 are respectively the same as the input module 11, the level transmission module 12, the output module 13, the first control terminal 131, the second control terminal 132, and the first isolation module 14. For details, refer to FIG. 1 and the related text content, which will not be repeated here.

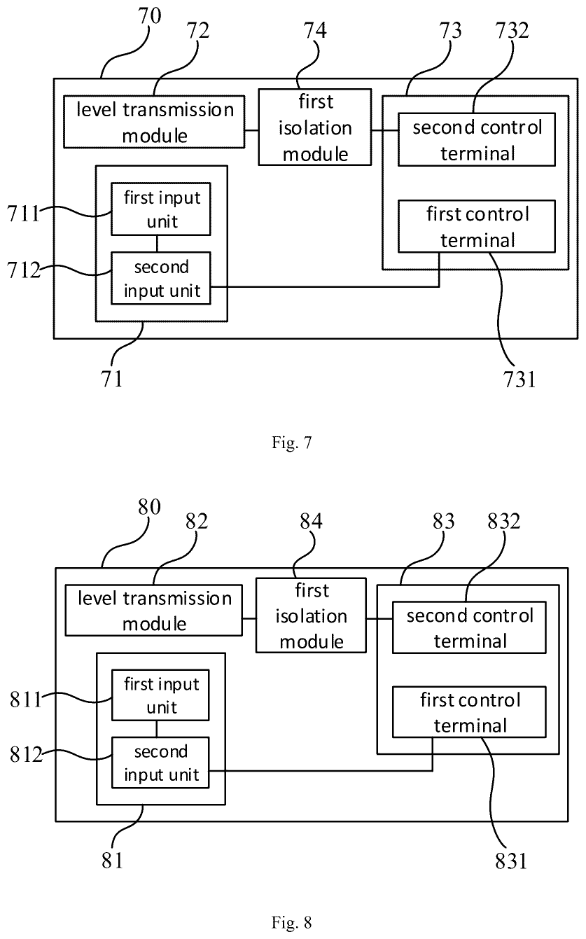

FIG. 7 is a schematic structural diagram of a seventh embodiment of the scan driving circuit of the present application. This embodiment is based on the sixth embodiment of the scan driving circuit provided in the present application. The input module 71 in the scan driving circuit 70 further includes a second input unit 712.

The second input unit 712 is connected in series between the first input unit 711 and a first node. The first input unit 711 is used to sample the scan input signal in response to the third clock signal, and the second input unit 712 is used to receive a first clock signal correspondingly provided by the timing control circuit, so as to trigger an action in response to the voltage level state of the first clock signal, thereby transmitting the scan input signal output by the first input unit 711 as a first control signal to the first node, thus enabling more stable transmission of the first control signal.

In one embodiment, the first input unit 711 includes a fourteenth transistor. A first terminal of the fourteenth transistor is connected to a supply terminal of the scan input signal, a control terminal of the fourteenth transistor is connected to a supply terminal of the third clock signal, and a second terminal of the fourteenth transistor is connected to the first node.

In one embodiment, the second input unit 712 includes a first transistor. A first terminal of the first transistor is connected to the second terminal of the fourteenth transistor, a control terminal of the first transistor is connected to a supply terminal of the first clock signal, and a second terminal of the first transistor is connected to the first node.

The control terminal of the fourteenth transistor can respond to the third clock signal to trigger an action, thereby turning on the first terminal and the second terminal of the fourteenth transistor to transmit the scan input signal to the first node or the first terminal of the first transistor. The control terminal of the first transistor can respond to the first clock signal to trigger an action, thereby turning on the first terminal and the second terminal of the first transistor to transmit the scan input signal to the first node.

In this embodiment, the level transmission module 72, the output module 73, the first control terminal 731, the second control terminal 732, and the first isolation module 74 are respectively the same as the level transmission module 62, the output module 63, the first control terminal 631, the second control terminal 632, and the first isolation module 64. For details, refer to FIG. 6 and the related text content, which will not be repeated here.

FIG. 8 is a schematic structural diagram of an eighth embodiment of a scan driving circuit according to the present application. This embodiment is based on the sixth embodiment of the scan driving circuit provided in the present application. The input module 81 in the scan driving circuit 80 further includes a second input unit 812.

The second input unit 812 is connected in series between the first input unit 811 and a first node. The first input unit 811 samples a scan input signal in response to a first clock signal, and the second input unit 812 transmits the scan input signal output from the first input unit 811 as a first control signal to the first node in response to a third clock signal.

In one embodiment, the first input unit 811 includes a fourteenth transistor, and the second input unit 812 includes a first transistor. A first terminal of the fourteenth transistor is connected to a providing terminal of the scan input signal, a control terminal of the fourteenth transistor is connected to a providing terminal of the first clock signal, and a second terminal of the fourteenth transistor is connected to a first terminal of the first transistor. A control terminal of the first transistor is connected to a providing terminal of the third clock signal, and a second terminal of the first transistor is connected to the first node.

Thus, it can be understood that the third clock signal and the first clock signal respectively received by the control terminals of the fourteenth transistor and the first transistor can be interchanged. Furthermore, only the fourteenth transistor or the first transistor correspondingly receiving the third clock signal may be retained, which is not limited in the present application.

In this embodiment, the level transmission module 82, the output module 83, the first control terminal 831, the second control terminal 832, and the first isolation module 84 are respectively the same as the level transmission module 62, the output module 63, the first control terminal 631, the second control terminal 632, and the first isolation module 64. For details, refer to FIG. 6 and related textual content, which will not be repeated here.

FIG. 9 is a schematic structural diagram of a ninth embodiment of a scan driving circuit according to the present application. This embodiment is based on the first embodiment of the scan driving circuit provided in the present application. The scan driving circuit 90 further includes a first control module 97.

The first control module 97 is connected to the first node, to be triggered to operate in response to the potential of the first node, to sample the first clock signal, and to transmit the first clock signal to the level transmission module 92.

In this embodiment, the input module 91, the level transmission module 92, the output module 93, the first control terminal 931, the second control terminal 932, and the first isolation module 94 are respectively the same as the input module 11, the level transmission module 12, the output module 13, the first control terminal 131, the second control terminal 132, and the first isolation module 14. For details, refer to FIG. 1 and related textual content, which will not be repeated here.

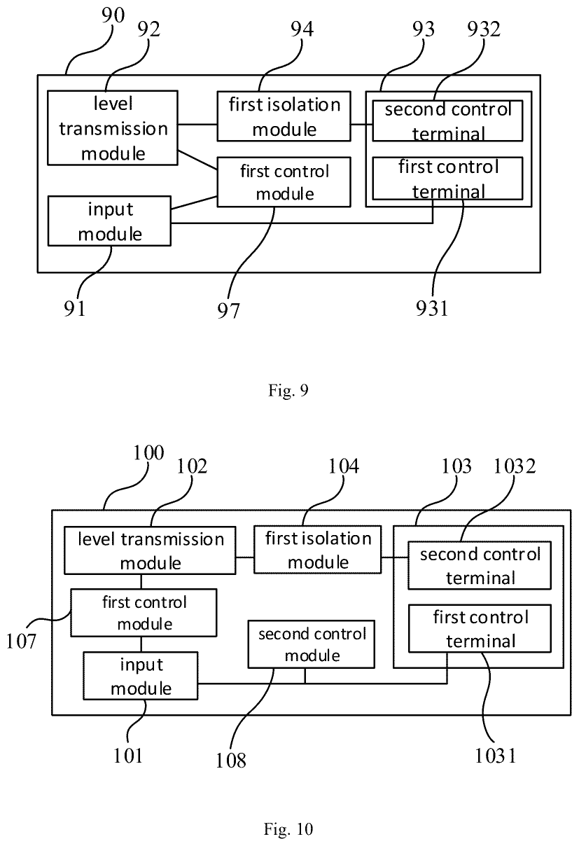

FIG. 10 is a schematic structural diagram of a tenth embodiment of a scan driving circuit according to the present application. This embodiment is based on the ninth embodiment of the scan driving circuit provided in the present application. The scan driving circuit 100 further includes a second control module 108.

The second control module 108 is connected to a first control terminal, the first node, an output terminal of the first control module 107, and a second level signal providing terminal, and is configured to receive a second level signal and a second clock signal correspondingly provided by a timing control circuit, and to be triggered to operate in response to the potential of the output terminal of the first control module 107 and the potential of the first node, to sample the second clock signal and the second level signal and transmit them to the first control terminal.

In this embodiment, the input module 101, the level transmission module 102, the output module 103, the first control terminal 1031, the second control terminal 1032, the first isolation module 104, and the first control module 107 are respectively the same as the input module 91, the level transmission module 92, the output module 93, the first control terminal 931, the second control terminal 932, the first isolation module 94, and the first control module 97. For details, refer to FIG. 9 and related textual content, which will not be repeated here.

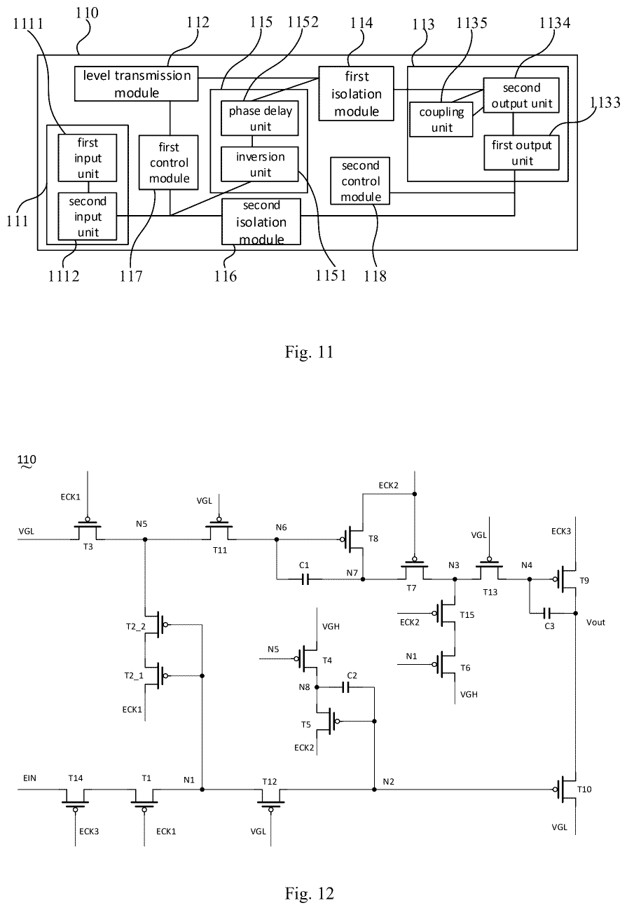

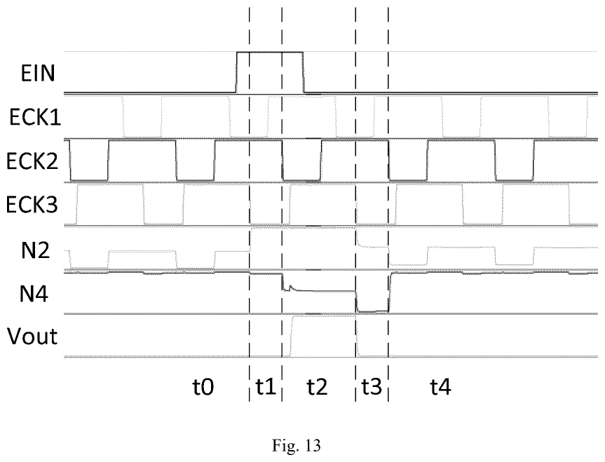

FIG. 11 is a schematic structural diagram of an eleventh embodiment of a scan driving circuit according to the present application. FIG. 12 is a schematic structural diagram of an embodiment of the scan driving circuit in FIG. 11. FIG. 13 is a schematic timing diagram of an embodiment of various input signals corresponding to the scan driving circuit in FIG. 12.

In this embodiment, the scan driving circuit 110 includes: an input module 111, a level transmission module 112, an output module 113, a first isolation module 114, an inversion module 115, a second isolation module 116, a first control module 117, and a second control module 118. The input module 111 includes a first input unit 1111 and a second input unit 1112. The inversion module 115 includes an inversion unit 1151 and a phase delay unit 1152. The output module 113 includes a first output unit 1133, a second output unit 1134, and a coupling unit 1135.

In this embodiment, each module and each unit in the scan driving circuit are respectively the same as each module, each unit with the same name, and the corresponding connection relationships and functions in FIGS. 1-10. For details, refer to FIGS. 1-10 and related textual content, which will not be repeated here.

In one embodiment, the first input unit 1111 includes a fourteenth transistor T14, the second input unit 1112 includes a first transistor T1, the inverter unit 1151 includes a sixth transistor T6, the phase delay unit 1152 includes a fifteenth transistor T15, the first output unit 1133 includes a tenth transistor T10, the second output unit 1134 includes a ninth transistor T9, the coupling unit 1135 includes a third capacitor C3, the level transmission module 112 includes a third transistor T3, an eleventh transistor T11, an eighth transistor T8, a seventh transistor T7, and a first capacitor C1, the first isolation module 114 includes a thirteenth transistor T13, the second isolation module 116 includes a twelfth transistor T12, the first control module 117 includes a second transistor T2, and the second transistor T2 is a composite transistor, that is, the second transistor T2 further includes a first single transistor T2-1 and a second single transistor T2-2, the second control module 118 includes a fourth transistor T4, a fifth transistor T5, and a second capacitor C2; and the connection relationships among the aforementioned transistors and capacitors are as shown in FIG. 12, and are correspondingly connected to an external timing control circuit, a supply terminal of a first level signal VGL, a supply terminal of a second level signal VGH, and a start signal supply terminal of a system processing circuit or an output terminal Vout of a previous-stage scan driving circuit 110, for receiving the first level signal VGL, the second level signal VGH, a first clock signal ECK1, a second clock signal ECK2, and a third clock signal ECK3 correspondingly provided by the timing control circuit, and a scan input signal EIN provided by the start signal supply terminal of the system processing circuit or the previous-stage scan driving circuit 110, and the level states of the respective clock signals are as shown in FIG. 4. For details, refer to FIGS. 12 and 13, which will not be elaborated here one by one.

In one embodiment, taking the first level signal VGL as a low-level signal and the second level signal VGH as a high-level signal, and the aforementioned transistors are P-type transistors, that is, triggered to conduct between a first terminal and a second terminal when their gate voltage is low-level, it can be known that in a first stage t0, the scan input signal EIN is provided as a first level state, i.e., a low-level state, and the first clock signal ECK1, the second clock signal ECK2 and the third clock signal ECK3 include the first level state, to trigger the fourteenth transistor T14, the first transistor T1, the sixth transistor T6, the fifteenth transistor T15, the thirteenth transistor T13, and the tenth transistor T10 to conduct, and a first node N1 and a second node N2 are correspondingly at low level, and a third node N3 and a fourth node N4 are correspondingly at high level, to trigger the ninth transistor T9 to turn off, thereby causing the output terminal Vout to correspondingly output a low-level signal.

In a second stage t1, the scan input signal EIN is provided as a second level state, i.e., a high-level state, and the first clock signal ECK1 and the third clock signal ECK3 are provided as the first level state, to trigger the fourteenth transistor T14, the first transistor T1, the third transistor T3, and the eleventh transistor T11 to conduct, a fifth node N5 and a sixth node N6 are correspondingly at low level, while the first node N1 and the second node N2 are correspondingly at high level, to trigger the eighth transistor T8 to conduct, while the second transistor T2, the sixth transistor T6, and the tenth transistor T10 are turned off, and the fourth node N4 remains at high level, to trigger the ninth transistor T9 to turn off, and the output terminal Vout continuously outputs a low-level signal.

In a third stage t2, the second clock signal ECK2 is provided as the first level state, to trigger the seventh transistor T7 to conduct, the first level signal VGL on the sixth node N6 is transmitted to the third node N3 and the fourth node N4 through the eighth transistor T8 and the seventh transistor T7, to trigger the ninth transistor T9 to conduct, and the output terminal Vout replicates and outputs the third clock signal ECK3, i.e., the third clock signal ECK3 currently at a high-level state, to output to a corresponding scan line, thereby outputting to a corresponding pixel unit via the scan line.

In a fourth stage t3, the scan input signal EIN is provided as the first level state, the second clock signal ECK2 is provided as the second level state, and the first clock signal ECK1 and the third clock signal ECK3 are provided as the first level state, to trigger the fourteenth transistor T14 and the first transistor T1 to conduct, while the fifteenth transistor T15 is triggered to turn off, and the first node N1 and the second node N2 are correspondingly at low level, and the tenth transistor T10 is triggered to conduct. At this time, because the third node N3 and the fourth node N4 are correspondingly at low level in the third stage, the fourth node N4 will be coupled to an extremely low level by the falling edge of the third clock signal ECK3 through the coupling effect of the third capacitor C3, to trigger the ninth transistor T9 to conduct and be fully turned on, and fully transmit the low level of the third clock signal ECK3 to the output terminal Vout, and the output terminal Vout correspondingly outputs a low-level signal.

Since the third node N3 is also at low level at this time, the voltage difference (voltage across) between the fourth node N4, i.e., the ninth transistor T9, and the seventh transistor T7 and the fifteenth transistor T15 can be effectively reduced by means of the thirteenth transistor T13, to avoid impact damage to the seventh transistor T7 and the fifteenth transistor T15 caused by the extremely low level, and in turn affect the stable output of the scan output signal by the output terminal Vout.

In a fifth stage t4, the second clock signal ECK2 is provided as the first level state, to trigger the fifteenth transistor T15 to conduct, and the second level signal VGH is transmitted to the third node N3 and the fourth node N4 through the sixth transistor T6 and the fifteenth transistor T15, to trigger the ninth transistor T9 to turn off; simultaneously, the second node N2 will be coupled to an extremely low level by the falling edge of the second clock signal ECK2 through the coupling effect of the second capacitor C2, and trigger the tenth transistor T10 to conduct and be fully turned on, and the first level signal VGL can be fully transmitted to the output terminal Vout, causing the output terminal Vout to correspondingly output a low-level signal.

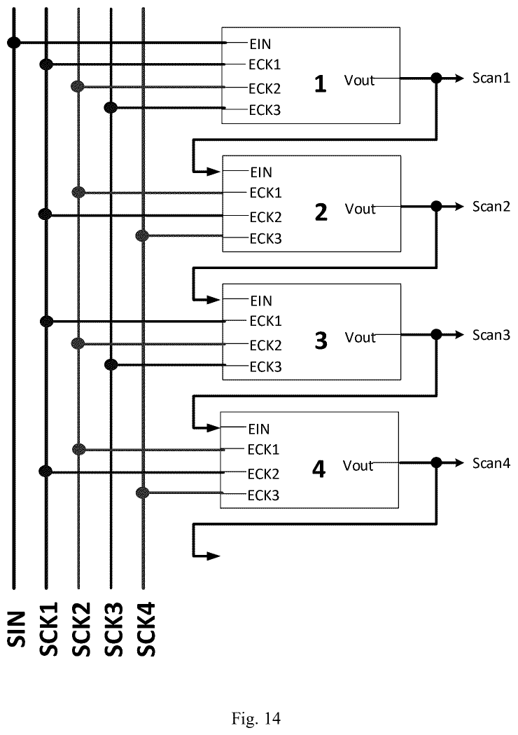

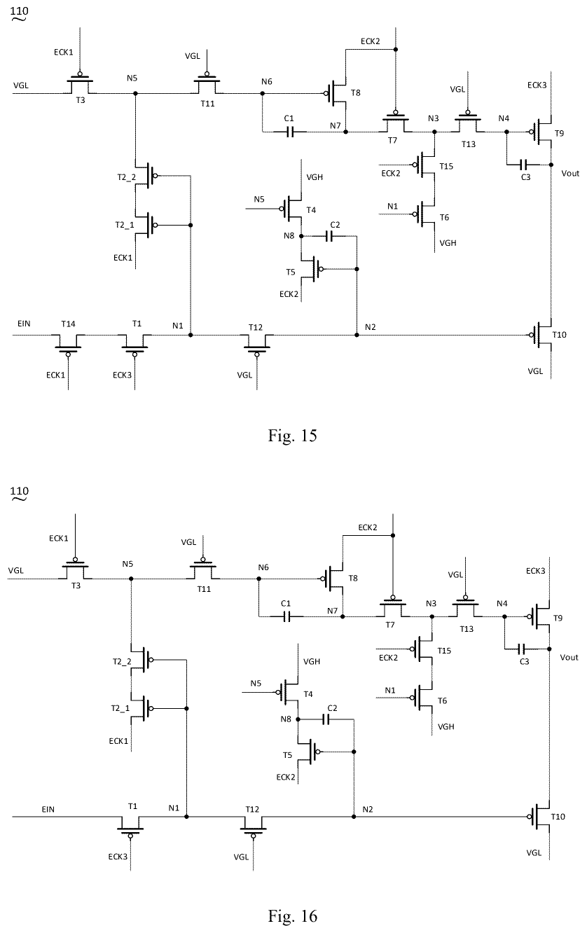

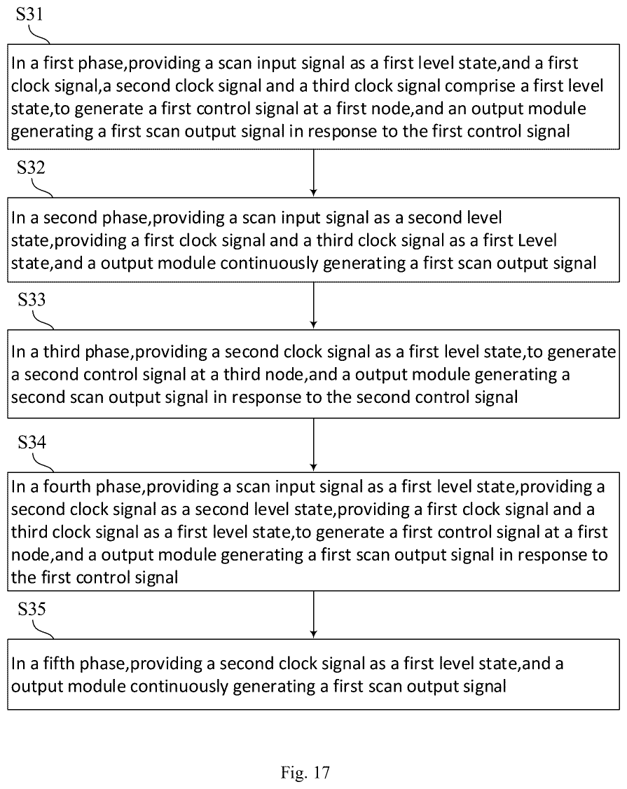

Similarly, since the first node N1 is also at a low level at this time, the voltage difference (voltage across) between the second node N2 and the first transistor T1, or between the tenth transistor T10 and the first transistor T1, can be effectively reduced by means of the twelfth transistor T12, to avoid impact damage to the first transistor T1 caused by an extremely low level, and in turn affect the stable output of the scanning output signal at the output terminal Vout. Refer to FIG. 14, which is a schematic structural diagram of an embodiment obtained by cascading the scan driving circuits in FIG. 12. In this embodiment, the number of the scan driving circuits 110 may be multiple, and they are cascaded with each other to respectively connect to an external timing control circuit, a start signal providing terminal of a system processing circuit, and a plurality of scanning lines, and receive a first initial clock signal SCK1, a second initial clock signal SCK2, a third initial clock signal SCK3, and a fourth initial clock signal SCK4 correspondingly provided by the timing control circuit, as well as a scanning start signal SIN sent by the start signal providing terminal, and after being adjusted by the plurality of scan driving circuits 110, corresponding scanning output signals are respectively output to the plurality of scanning lines, for example, a first scanning output signal SCN1, a second scanning output signal SCN2, a third scanning output signal SCN3, and a fourth scanning output signal SCN4, and are provided to corresponding pixel units via the plurality of scanning lines. Here, the scanning input signal EIN of each scan driving circuit 110 is the scanning output signal output by the previous-stage scan driving circuit 110, or the scanning start signal SIN of the scan driving circuit 110. The number of the scan driving circuits 110 may be any reasonable number such as 4, 6, or 8, which is not limited in this application. The waveform and phase of the first initial clock signal SCK1 are the same as those of the third initial clock signal SCK3, and the waveform and phase of the second initial clock signal SCK2 are the same as those of the fourth initial clock signal SCK4; the waveform of the third initial clock signal SCK3 is the same as that of the fourth initial clock signal SCK4, and both have a period of 2 h, with a phase difference of 1 h between the third initial clock signal SCK3 and the fourth initial clock signal SCK4. Refer to FIG. 15, which is a schematic structural diagram of another embodiment of the scan driving circuit in FIG. 11. The difference between the scan driving circuit 110 in this embodiment and the scan driving circuit 110 in FIG. 12 is that the clock signals connected to the control terminals of the first transistor T1 and the fourteenth transistor T14 are swapped. Continue to refer to FIG. 16, which is a schematic structural diagram of yet another embodiment of the scan driving circuit in FIG. 11. The difference between the scan driving circuit 110 in this embodiment and the scan driving circuit 110 in FIG. 12 is that the fourteenth transistor T14 is removed. This application also provides a driving method. Refer to FIG. 17, which is a schematic flowchart of an embodiment of the driving method of this application. It may include the following steps: S31: In a first stage, a scanning input signal is provided as a first level state, and a second clock signal and a third clock signal have a first level state, to generate a first control signal at a first node, and an output module generates a first scanning output signal in response to the first control signal. The driving method in this embodiment is a method for the scan driving circuit in a display panel to output a scanning signal to the scan driving circuit shown in FIG. 4. For details, refer to FIG. 4 and related text content, which will not be repeated here. As shown in FIG. 13, in the first stage, the scanning input signal is provided as a first level state, and the second clock signal and the third clock signal have a first level state, to trigger an input module, an inversion unit, and a phase delay unit to turn on, and generate a first control signal at the first node, and the output module generates a first scanning output signal in response to the first control signal. S32: In a second stage, the scanning input signal is provided as a second level state, and the first clock signal and the third clock signal are provided as a first level state, and the output module continuously generates the first scanning output signal. In this embodiment, in the second stage, the scanning input signal is provided as a second level state, and the first clock signal and the third clock signal are provided as a first level state, to trigger the input module to turn on, and the first node and a third node are set high, and trigger the inversion unit to turn off, and the output module continuously generates the first scanning output signal. S33: In a third stage, the second clock signal is provided as a first level state, to generate a second control signal at the third node, and the output module generates a second scanning output signal in response to the second control signal. In this embodiment, in the third stage, the second clock signal is provided as a first level state, to trigger a level transmission module to turn on, and provide a first level signal to the output module via the level transmission module, to generate a second control signal at the third node, and the output module generates a second scanning output signal in response to the second control signal. S34: In a fourth stage, the scanning input signal is provided as a first level state, the second clock signal is provided as a second level state, and the first clock signal and the third clock signal are provided as a first level state, to generate a first control signal at the first node, and the output module generates a first scanning output signal in response to the first control signal. In the fourth stage, the scanning input signal is provided as a first level state, the second clock signal is provided as a second level state, and the first clock signal and the third clock signal are provided as a first level state, to trigger the input module, the inversion unit, and the phase delay unit to turn on, to generate a first control signal at the first node, and the output module generates a first scanning output signal in response to the first control signal. S35: In a fifth stage, the second clock signal is provided as a first level state, and the output module continuously generates the first scanning output signal. In the fifth stage, the second clock signal is provided as a first level state, and the output module continuously generates the first scanning output signal. In some other embodiments, the scan driving circuit further includes some other more features, to be able to correspondingly implement some other more driving methods. For details, refer to FIG. 1 to FIG. 16 and related text content, which will not be repeated here.

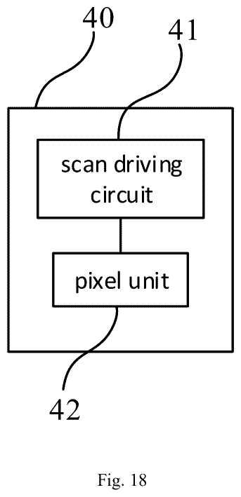

The present application also provides a display panel. Refer to FIG. 18, which is a schematic structural diagram of an embodiment of the display panel according to the present application. In this embodiment, the display panel 120 includes a scan driving circuit 121 and a pixel unit 122 that are coupled to each other. The scan driving circuit 121 described in this embodiment is the scan driving circuit 10, scan driving circuit 20, scan driving circuit 30, scan driving circuit 40, scan driving circuit 50, scan driving circuit 60, scan driving circuit 70, scan driving circuit 80, scan driving circuit 90, scan driving circuit 100, or scan driving circuit 110 described in any of the above embodiments. For details, refer to FIG. 1 to FIG. 16 and the related textual content, which will not be repeated here. The beneficial effect of the present application is as follows: In the scan driving circuit provided by the present application, the input module is used to generate a first control signal at a first node, the level transmission module is used to generate a second control signal at a third node, and the output module includes a first control terminal and a second control terminal. The first control terminal and the second control terminal are respectively used to electrically connect the input module and the level transmission module, to respectively respond to the first control signal and the second control signal to generate a corresponding scan output signal. Moreover, a first isolation module is further provided between the second control terminal of the output module and the third node, to minimize the cross-voltage between the level transmission module and the output module as much as possible, thereby enabling stable output of the scan output signal and effectively improving the reliability of the scan driving circuit.

What is claimed is:

1. A scan driving circuit, comprising:
an input module, configured to generate a first control signal at a first node;
a level transmission module, configured to generate a second control signal at a third node;
an output module, comprising a first control terminal and a second control terminal, wherein the first control terminal is configured to electrically connect the input module, the second control terminal is configured to electrically connect the level transmission module, so as to respond to the first control signal and the second control signal to generate a corresponding scan output signal;
a first isolation module, located between the second control terminal of the output module and the third node.

2. The scan driving circuit according to claim 1, wherein
the input module samples a scan input signal at least in response to a third clock signal to generate the first control signal at the first node;
the level transmission module samples a first level signal in response to a first clock signal and a second clock signal to generate the second control signal at the third node; wherein the first clock signal, the second clock signal, and the third clock signal have the same period, a phase difference between the second clock signal and the first clock signal is half a period, and a rising edge of the third clock signal occurs at or after a falling edge of the second clock signal.

3. The scan driving circuit according to claim 1, further comprising:
an inversion module, wherein the inversion module samples a second level signal in response to the first control signal at the first node and a second clock signal, and transmits the second level signal to the third node.

4. The scan driving circuit according to claim 3, wherein the inversion module comprises:
an inversion unit, connected to the first node, configured to sample the second level signal in response to the first control signal at the first node;
a phase delay unit, connected to the inversion unit and the third node, wherein the phase delay unit performs phase delay on the second level signal output by the inversion unit in response to the second clock signal and transmits the second level signal to the third node.

5. The scan driving circuit according to claim 4, wherein
the inversion unit comprises a sixth transistor, the phase delay unit comprises a fifteenth transistor, a first terminal of the sixth transistor is connected to a providing terminal of the second level signal, a control terminal of the sixth transistor is connected to the first node, a second terminal of the sixth transistor is connected to a first terminal of the fifteenth transistor, a control terminal of the fifteenth transistor is connected to a providing terminal of the second clock signal, and a second terminal of the fifteenth transistor is connected to the third node.

6. The scan driving circuit according to claim 1, wherein the output module comprises:
a first output unit, wherein a control terminal of the first output unit serves as the first control terminal of the output module, a first terminal of the first output unit receives a first level signal, a second terminal of the first output unit is connected to an output terminal of the output module, and the first output unit transmits the first level signal as the scan output signal to the output terminal of the output module in response to the first control signal;
a second output unit, wherein a control terminal of the second output unit serves as the second control terminal of the output module, a first terminal of the second output unit receives a third clock signal, a second terminal of the second output unit is connected to the output terminal of the output module, and the second output unit transmits the third clock signal as the scan output signal to the output terminal of the output module in response to the second control signal;
a coupling unit, wherein a first terminal of the coupling unit is connected to the control terminal of the second output unit, and a second terminal of the coupling unit is connected to the second terminal of the second output unit.

7. The scan driving circuit according to claim 6, wherein
the first output unit comprises a tenth transistor, the second output unit comprises a ninth transistor, the coupling unit comprises a third capacitor, a first terminal of the tenth transistor is connected to a providing terminal of the first level signal, a control terminal of the tenth transistor is connected to the first control terminal, a second terminal of the tenth transistor is connected to the output terminal of the output module, a first terminal of the ninth transistor is connected to a providing terminal of the third clock signal, a control terminal of the ninth transistor is connected to a first terminal of the third capacitor and the second control terminal, and a second terminal of the ninth transistor is connected to a second terminal of the third capacitor and the output terminal of the output module.

8. The scan driving circuit according to claim 1, further comprising:
a second isolation module, disposed between the first control terminal of the output module and the first node.

9. The scan driving circuit according to claim 1, wherein the input module comprises: a first input unit configured to sample a scan input signal in response to a third clock signal.

10. The scan driving circuit according to claim 9, wherein the input module further comprises a second input unit, the second input unit being connected in series between the first input unit and the first node, and the second input unit being configured to transmit the scan input signal output from the first input unit as the first control signal to the first node in response to a first clock signal.

11. The scan driving circuit according to claim 10, wherein the first input unit comprises a fourteenth transistor, a first terminal of the fourteenth transistor is connected to a supply terminal of the scan input signal, a control terminal of the fourteenth transistor is connected to a supply terminal of the third clock signal, and a second terminal of the fourteenth transistor is connected to the first node.

12. The scan driving circuit according to claim 11, wherein the second input unit comprises a first transistor, a first terminal of the first transistor is connected to the second terminal of the fourteenth transistor, a control terminal of the first transistor is connected to a supply terminal of the first clock signal, and a second terminal of the first transistor is connected to the first node.

13. The scan driving circuit according to claim 1, wherein the input module comprises: a first input unit and a second input unit, the second input unit being connected in series between the first input unit and the first node, the first input unit being configured to sample a scan input signal in response to a first clock signal, and the second input unit being configured to transmit the scan input signal output from the first input unit as the first control signal to the first node in response to a third clock signal.

14. The scan driving circuit according to claim 13, wherein the first input unit comprises a fourteenth transistor, the second input unit comprises a first transistor, a first terminal of the fourteenth transistor is connected to a supply terminal of the scan input signal, a control terminal of the fourteenth transistor is connected to a supply terminal of the first clock signal, a second terminal of the fourteenth transistor is connected to a first terminal of the first transistor, a control terminal of the first transistor is connected to a supply terminal of the third clock signal, and a second terminal of the first transistor is connected to the first node.

15. The scan driving circuit according to claim 1, further comprising:
a first control module, configured to sample a first clock signal and transmit the first clock signal to the level transmission module in response to a potential of the first node.

16. The scan driving circuit according to claim 15, further comprising:
a second control module, connected to the first control terminal and an output terminal of the first control module, and configured to sample a second clock signal and a second level signal, and transmit the second clock signal and the second level signal to the first control terminal in response to a potential of the output terminal of the first control module and the potential of the first node.

17. The scan driving circuit according to claim 1, wherein a scan input signal is a scan output signal output from a previous-stage scan driving circuit.

18. The scan driving circuit according to claim 1, wherein the scan input signal is a scan start signal of the scan driving circuit.

19. A driving method, applied to the scan driving circuit according to claim 1, comprising:
in a first phase, providing the scan input signal as a first level state, and the first clock signal, a second clock signal and a third clock signal comprising the first level state, to generate a first control signal at a first node, and an output module generating a first scan output signal in response to the first control signal;
in a second phase, providing the scan input signal as a second level state, providing the first clock signal and the third clock signal as the first level state, and the output module continuously generating the first scan output signal;
in a third phase, providing the second clock signal as the first level state, to generate a second control signal at a third node, and the output module generating a second scan output signal in response to the second control signal;
in a fourth phase, providing the scan input signal as the first level state, providing the second clock signal as the second level state, providing the first clock signal and the third clock signal as the first level state, to generate the first control signal at the first node, and the output module generating the first scan output signal in response to the first control signal;
in a fifth phase, providing the second clock signal as the first level state, and the output module continuously generating the first scan output signal.

20. A display panel, wherein the display panel comprises:
a scan driving circuit and a pixel unit coupled to each other; wherein the scan driving circuit is the scan driving circuit, comprising:
an input module, configured to generate a first control signal at a first node;
a level transmission module, configured to generate a second control signal at a third node;
an output module, comprising a first control terminal and a second control terminal, wherein the first control terminal is configured to electrically connect the input module, the second control terminal is configured to electrically connect the level transmission module, so as to respond to the first control signal and the second control signal to generate a corresponding scan output signal;
a first isolation module, located between the second control terminal of the output module and the third node.
